(19) United States
(12) Patent Application Publication
(10) Pub. No.: US 2024/0071557 A1
(43) Pub. Date: Feb. 29, 2024

(54) FAILURE ANALYSIS METHOD, COMPUTER EQUIPMENT, AND STORAGE MEDIUM

(71) Applicant: CHANGXIN MEMORY TECHNOLOGIES, INC., Hefei City, Anhui (CN)

(72) Inventors: Zhi YANG, Hefei City, Anhui (CN); Lixia ZHANG, Hefei City, Anhui (CN); Hao HE, Hefei City, Anhui (CN)

(73) Assignee: CHANGXIN MEMORY TECHNOLOGIES, INC., Hefei City, Anhui (CN)

(21) Appl. No.: 17/607,395

(22) PCT Filed: Jun. 23, 2021
(86) PCT No.: PCT/CN2021/101736

§ 371 Date: Aug. 4, 2022

(30) Foreign Application Priority Data
Jan. 26, 2021 (CN) 202110105459.8

(51) Int. Cl. G11C 29/56

(52) U.S. Cl. CPC G11C 29/56008; G11C 29/56004

(57) ABSTRACT

A failure analysis method includes: obtaining failure data of IO channels in a target chip particle, the target chip particle including a plurality of physical modules, a number of the plurality of physical modules is M, and each physical module including a plurality of IO channels, wherein M is a positive integer greater than or equal to 2; splitting the failure data to form M groups of module failure data corresponding to the physical modules; determining a partial failure type of each physical module according to each module failure data; and determining a storage failure type of the target chip particle according to the partial failure type of each physical module.

### CROSS-REFERENCE TO RELATED APPLICATIONS

The present application claims priority to Chinese Patent Application No. 2021101054598, titled “FAILURE ANALYSIS METHOD, COMPUTER EQUIPMENT, AND STORAGE MEDIUM”, filed on Jan. 26, 2021, which is incorporated herein by reference in its entirety.

### TECHNICAL FIELD

The present application relates to the field of storage technology, and in particular, to a failure analysis method, computer equipment, and a storage medium.

### BACKGROUND

A storage system is one of the important components of a computer. The storage system provides the ability to write and read information (programs and data) needed by the operation of the computer to achieve an information memory function of the computer.

The storage failure type of each chip particle in the storage system is usually manually determined, which consumes a lot of time and labor costs and limits the speed and efficiency of analysis.

### SUMMARY

Based on this, it is necessary to provide a failure analysis method that can improve the efficiency of failure analysis, computer equipment, and a storage medium in response to the above technical problems.

According to multiple embodiments, the first aspect of the present application provides a failure analysis method, including:
obtaining failure data of IO channels in a target chip particle, the target chip particle including a plurality of physical modules, a number of the plurality of physical modules is M, and each physical module including a plurality of TO channels, wherein M is a positive integer greater than or equal to 2;
splitting the failure data to form M groups of module failure data corresponding to the physical modules;
determining a partial failure type of each physical module according to each module failure data; and
determining a storage failure type of the target chip particle according to the partial failure type of each physical module.

According to multiple embodiments, the second aspect of the present application provides a computer equipment, including a memory and a processor, the memory storing a computer program, wherein when the processor executes the computer program, the steps of any one of the above-mentioned failure analysis methods are implemented.

According to multiple embodiments, the third aspect of the present application provides a computer-readable storage medium, storing a computer program thereon, wherein when the computer program is executed by a processor, the steps of any one of the above-mentioned failure analysis methods are implemented.

According to the above-mentioned failure analysis method, computer equipment and storage medium, failure data of IO channels in a target chip particle is obtained and split according to physical modules, so that a storage failure type of the target chip particle can be quickly, effectively and automatically determined according to the characteristics of the physical modules.

### BRIEF DESCRIPTION OF THE DRAWINGS

In order to explain technical solutions in embodiments of the present application or in the prior art more clearly, the accompanying drawings to be used for describing the embodiments of the present application or the prior art will be introduced simply. Apparently, the accompanying drawings to be described below are merely some embodiments of the present application. A person of ordinary skill in the art may obtain other drawings according to these drawings without paying any creative effort.

FIG. 1 is a schematic flowchart of a failure analysis method in an embodiment;

FIG. 2 is a schematic flowchart of a failure analysis method in another embodiment;

FIG. 3 is a schematic flowchart of a failure analysis method in still another embodiment;

FIG. 4 is a schematic diagram of a process of determining a partial failure type of each physical module in an embodiment;

FIG. 5 is a schematic flowchart of a method for determining a single-channel failure category in an embodiment;

FIG. 6 is a schematic flowchart of a method for determining a single-channel failure category in another embodiment;

FIG. 7 is a schematic flowchart of a method for determining a multi-channel failure category in an embodiment;

FIG. 8 is a schematic flowchart of a failure analysis method in still another embodiment.

### DETAILED DESCRIPTION

In order to facilitate the understanding of the present application, the present application will be described more comprehensively below with reference to the relevant accompanying drawings. Embodiments of the present application are shown in the drawings. However, the present application may be implemented in many different forms, and is not limited to the embodiments described herein. Rather, these embodiments are provided so that the disclosure of the present application is more thorough and comprehensive.

Unless otherwise defined, all technological and scientific terms used herein have the same meanings as commonly understood by those of ordinary skill in the technical field of the present application. The terms used in the description of the present application are only for the purpose of describing specific embodiments, but are not intended to limit the present application.

It may be understood that the terms “first”, “second”, etc. used in the present application may be used herein to describe various features, but these features are not limited by these terms. These terms are only used to distinguish the first feature from another.

When used herein, the singular forms of “a”, “an” and “the” may also include plural forms, unless the context clearly indicates otherwise. It should also be understood that the terms “comprise/include” or “have” and the like designate the existence of the stated features, wholes, steps, operations, components, parts, or combinations thereof, but do not exclude the existence or addition of one or more other features, wholes, steps, operations, components, parts, or combinations thereof. Meanwhile, the term “and/or” used in the description includes any and all combinations of relevant items listed.

The failure analysis method, computer equipment, and storage medium provided in the present application may be applied to failure analysis of system-level failure data of various different types of storage systems, for example, applied to failure analysis of system-level failure data of a double data rate synchronous dynamic random access memory (DDR) system.

Alternatively, the failure analysis method, computer equipment, and storage medium provided in the present application may also be applied to failure analysis of failure data of various different types of monolithic chip particles.

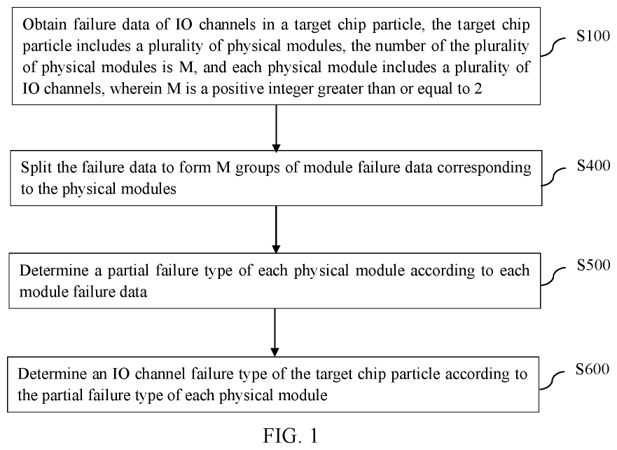

In one embodiment, referring to FIG. 1, a failure analysis method is provided, including:
Step S100, failure data of IO channels in a target chip particle is obtained, the target chip particle having a plurality of physical modules, the number of the plurality of physical modules is M, wherein M is a positive integer greater than or equal to 2;
Step S400, the failure data is split to form M groups of module failure data corresponding to the physical modules;
Step S500, a partial failure type of each physical module is determined according to each module failure data;
Step S600, a storage failure type of the target chip particle is determined according to the partial failure type of each physical module.

As an example, the method in this embodiment may be used for failure analysis of system-level failure data of a storage system. The storage system may include a plurality of chip particles, the number of the plurality of chip particles is N, where N is a positive integer greater than or equal to 2. That is, the storage system may include a plurality of chip particles.

Specifically, each chip particle may include a plurality of physical modules, and the physical modules are banks. Each physical module may form a bank. Also, each physical module may include a plurality of storage units. Each storage unit can output one bit of test data once when it is turned on. Understandably, when the chip particles are tested, there are normal data and failure data among the test data of all the storage units. The “failure data” mentioned herein is the failure data among the test data.

In addition, each physical module may include a plurality of IO channels. Each IO channel is connected to part of the storage units correspondingly, so that each storage unit outputs data through the corresponding IO channel.

Understandably, “a plurality of” here may be one or more. When the number of IO channels in the physical module is one, the storage units in the physical module are connected to the same IO channel.

Then, the target chip particle in step S100 is each chip particle in the storage system. Before the failure data of IO channels in the target chip particle is obtained, an original test document of the storage system may be read first. The original test document of the storage system may be an original document of all failure data in the storage system. Then, the original test document of the storage system is split to obtain failure data of each chip particle.

Understandably, the original test document of the storage system includes failure data of all chip particles in a test. Splitting the original test document of the storage system to obtain failure data of a chip particle may be extracting the failure data of the chip particle from the original test document.

Of course, the method in this embodiment may be used for failure analysis of failure data of a single chip particle.

In step S400, the failure data of IO channels in the target chip particle may be split according to the physical modules inside the target chip particle to form M groups of module failure data corresponding to the physical modules.

Also understandably, the failure data of IO channels in the target chip particle here includes failure data of all physical modules in a test. Splitting the failure data of IO channels in the target chip particle to form a group of module failure data corresponding to a physical module may be extracting a group of failure data of the physical module from the failure data of IO channels in the target chip particle.

Since the target chip particle includes a plurality of physical modules, associated storage units are usually located in the same physical module. Therefore, the failure data of IO channels in the target chip particle is split according to the physical modules, so that failure analysis can be performed more accurately.

Meanwhile, when the target chip particle is tested, there may be repeated tests. Therefore, while the failure data of IO channels in the target chip particle is split, repeated failure data can also be removed.

In step S500, partial failure types of all physical modules may be determined according to the corresponding module failure data.

In step S600, after the partial failure types of all the physical modules are determined, the storage failure type of the target chip particle may be comprehensively determined according to the partial failure types of all the physical modules.

As an example, the final storage failure type of the target chip particle may be determined according to the priority levels of various partial failure types of the physical modules, and outputted.

Specifically, the priority levels of various partial failure types may be determined according to actual conditions. For example, larger failure area, failure data related to IO channel problems, more failed physical modules, etc. are all serious failures. Therefore, the priority levels of various partial failure types can be comprehensively determined according to the size of the failure area, whether the failure data is related to IO channel problems, the number of failed physical modules, etc.

In the method of this embodiment, failure data of IO channels in a target chip particle is obtained and split according to physical modules, so that a storage failure type of the target chip particle can be quickly, effectively and automatically determined according to the characteristics of the physical modules.

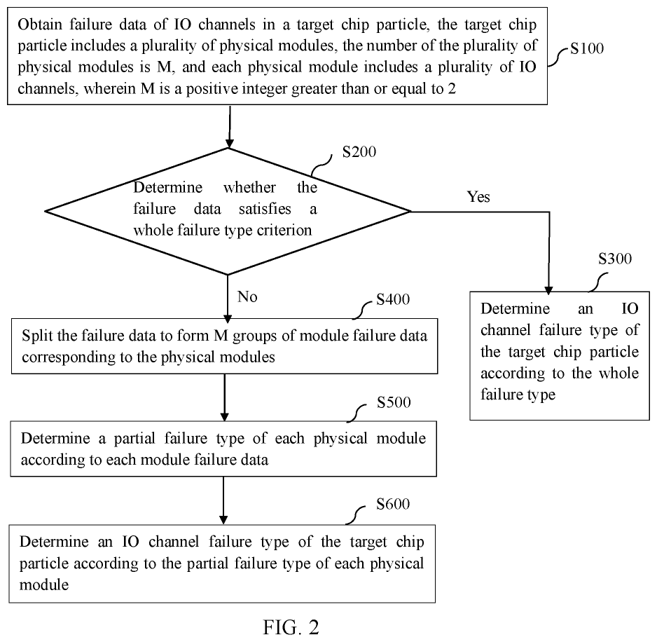

In one embodiment, referring to FIG. 2, before step S600 and after step S100, the method further includes:
Step S200, whether the failure data satisfies a whole failure type criterion is determined;
Step S300, if the failure data satisfies the whole failure type criterion, the storage failure type of the target chip particle is determined according to the whole failure type.

If the failure data does not satisfy the whole failure type criterion, the storage failure type of the target chip particle is determined according to the partial failure type of each physical module.

Specifically, if the failure data does not satisfy the whole failure type criterion, step S400 may be performed, and steps S400, S500, and S600 are performed in order.

Of course, steps S200, S300, S400, and S500 are not necessarily performed in this order, and there is no strict order restriction. These steps may be performed in other reasonable order, which is not limited in the present application.

Step S200, the whole failure type criterion is a criterion for determining whether the failure data of IO channels of the target chip particle has certain regular characteristics as a whole, so as to quickly determine the storage failure type of the target chip particle.

In the method of this embodiment, when the failure data of IO channels in the target chip particle satisfies the whole failure type criterion, the storage failure type of the target chip particle is determined according to the whole failure type.

When the failure data of IO channels in the target chip particle does not satisfy the whole failure type criterion, the storage failure type of the target chip particle is determined according to the partial failure type of each physical module.

Therefore, this embodiment can accurately and efficiently determine the storage failure type of the target chip particle through a combination of whole and partial analysis.

In one embodiment, the failure analysis method is applied to failure analysis of a storage system, the storage system including a plurality of chip particles, the number of the plurality of chip particles is N, where N is a positive integer greater than or equal to 2. The whole failure type criterion includes a system-level whole failure criterion and a particle-level whole failure criterion.

The system-level whole failure criterion is a basis for representing whole failure of failure data of IO channels on chip particles including the target chip particle in the storage system, for example, a basis for representing a whole contact failure.

The particle-level whole failure criterion is a basis for representing whole failure of failure data of IO channels in the target particle, for example, a basis for representing a whole block move failure.

At this point, failure analysis can be performed more comprehensively in combination with system characteristics and particle characteristics.

In one embodiment, the system-level whole failure criterion includes a contact failure type criterion.

When the storage system is tested, it is usually put into a test carrier such that each chip particle thereon is in electrical contact with the carrier for testing. The contact failure may specifically be a failure caused by poor contact between the chip particles and the carrier.

The contact failure type criterion indicates simultaneous failure of failure data of a preset number of IO channels of other chip particles.

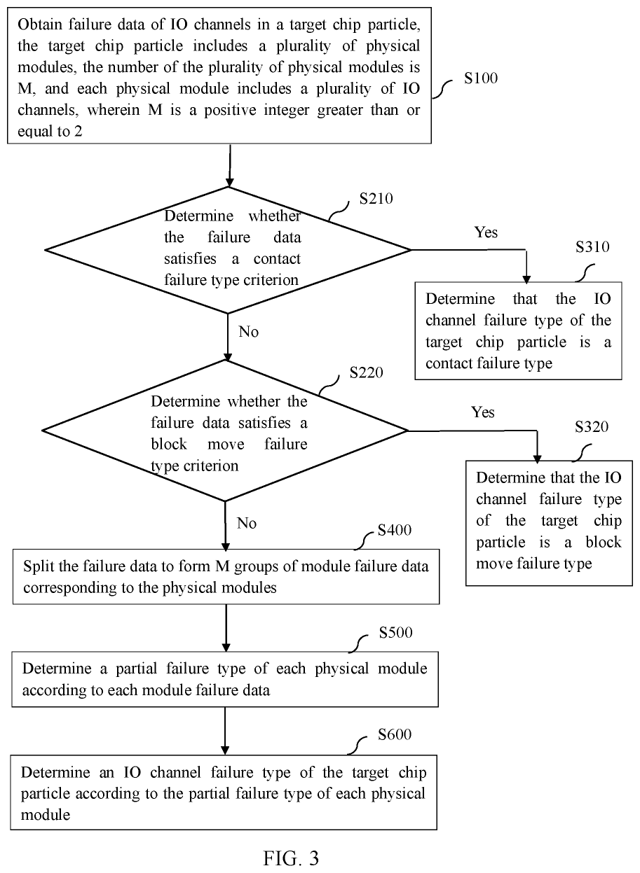

Then, referring to FIG. 3, step S200 includes:
Step S210, whether the failure data satisfies a contact failure type criterion is determined;
Step S300 includes:
Step S310, if the failure data satisfies the contact failure type criterion, it is determined that the storage failure type of the target chip particle is a contact failure type.

That is, if among the failure data of IO channels in the target chip particle, the failure data of IO channels greater than a preset number are all failure data, then it is determined that the storage failure type of the target chip particle is the contact failure type.

In one embodiment, on the basis of the foregoing embodiment, after step S210, if the failure data does not satisfy the contact failure type criterion, a particle-level whole failure type determination is performed. The particle-level whole failure criterion includes a block move failure type criterion.

Specifically, when the storage system is tested, various pattern tests are usually performed, and the various pattern tests may include a block move pattern test. The block move pattern is data block move between different chip particles.

Therefore, the failure data of IO channels of each chip particle in the storage system usually includes various types of failure data. The various types of failure data include failure data of the block move pattern test.

The block move failure type criterion indicates that the failure data is test data of the block move pattern test.

Then, referring to FIG. 3, step S200 further includes:
Step S220, if the failure data does not satisfy the contact failure type criterion, whether the failure data satisfies a block move failure type criterion is determined.
Step S300 includes:
Step S320, if the failure data satisfies the block move failure type criterion, it is determined that the storage failure type of the target chip particle is a block move failure type;

At this time, if the failure data does not satisfy the block move failure type criterion, the storage failure type of the target chip particle is determined according to the partial failure type of each physical module.

It may be understood that, in the embodiments of the present application, the whole failure type is not limited to the contact failure type and the block move failure type in the foregoing embodiments. The whole failure type may also be or include other forms of whole failure types. Correspondingly, steps S200, S300, etc. are not limited to the form in the foregoing embodiments.

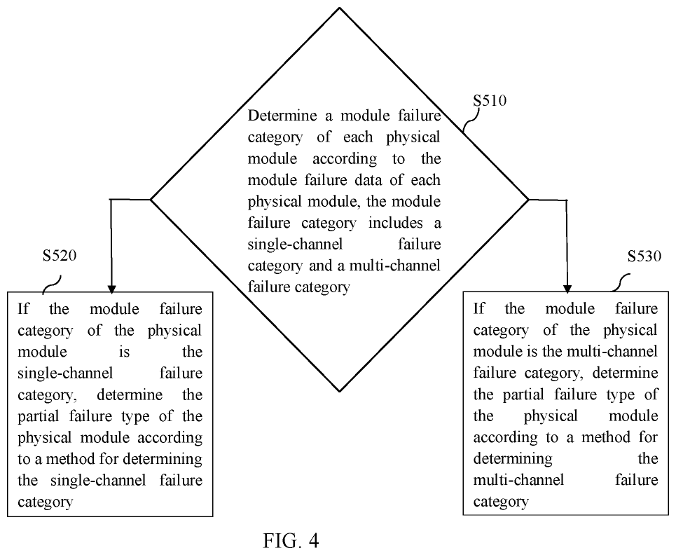

In one embodiment, referring to FIG. 4, step S500 includes:
Step S510, a module failure category of each physical module is determined according to the module failure data of each physical module, the module failure category including a single-channel failure category and a multi-channel failure category;
Step S520, if the module failure category of the physical module is the single-channel failure category, the partial failure type of the physical module is determined according to a method for determining the single-channel failure category;
Step S530, if the module failure category of the physical module is the multi-channel failure category, the partial failure type of the physical module is determined according to a method for determining the multi-channel failure category.

As an example, in step S510, for each physical module, the method for determining the module failure category may include:
Step S511, whether all the failure data in the physical module are data corresponding to the same IO channel is determined according to the module failure data;
step S512, if all the failure data in the physical module are data corresponding to the same IO channel, it is determined that the module failure category of the physical module is the single-channel failure category;
Step S513, if all the failure data in the physical module are not the data corresponding to the same IO channel (that is, all the failure data in the physical module correspond to the data of a plurality of IO channels), it is determined that the module failure category of the physical module is the multi-channel failure category.

This embodiment first determines the module failure category of the physical module according to the situation of the IO channel corresponding to the failure data in the physical module. Then, the partial failure type of each physical module is determined according to a different method for determining the corresponding module failure category, so that the determination on the partial failure type of each physical module is more accurate.

In one embodiment, the physical module includes a plurality of storage units arranged in an array. Each storage unit outputs data through a corresponding IO channel.

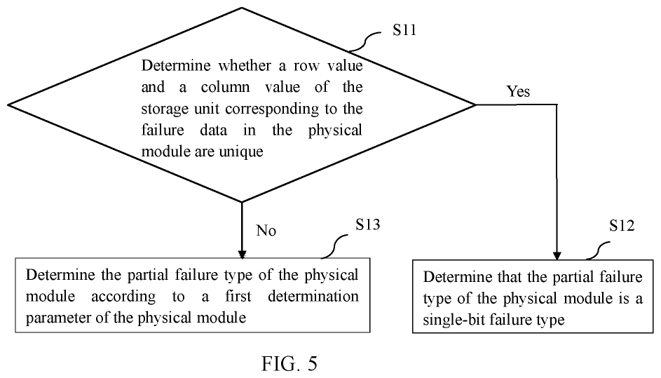

Referring to FIG. 5, the method for determining the single-channel failure category in step S520 includes:
Step S11, whether a row value and a column value of the storage unit corresponding to the failure data in the physical module are unique;
Step S12, if the row value and the column value of the storage unit corresponding to the failure data in the physical module are unique, it is determined that the partial failure type of the physical module is a single-bit failure type;
Step S13, if the row value and the column value of the storage unit corresponding to the failure data in the physical module are not unique, the partial failure type of the physical module is determined according to a first determination parameter of the physical module.

In one embodiment, the first determination parameter includes at least a maximum row spacing, a minimum row spacing, a maximum column spacing, a minimum column spacing, a row continuous spacing ratio and a column continuous spacing ratio between the storage units corresponding to each failure data, the row continuous spacing ratio is a ratio of failure data whose row spacing between the corresponding storage units is less than or equal to a row spacing threshold, and the column continuous spacing ratio is a ratio of failure data whose column spacing between the corresponding storage units is less than or equal to a column spacing threshold.

The first determination parameter may be obtained before step S13. For example, it may be obtained, but not limited to, after step S4 and before step S520.

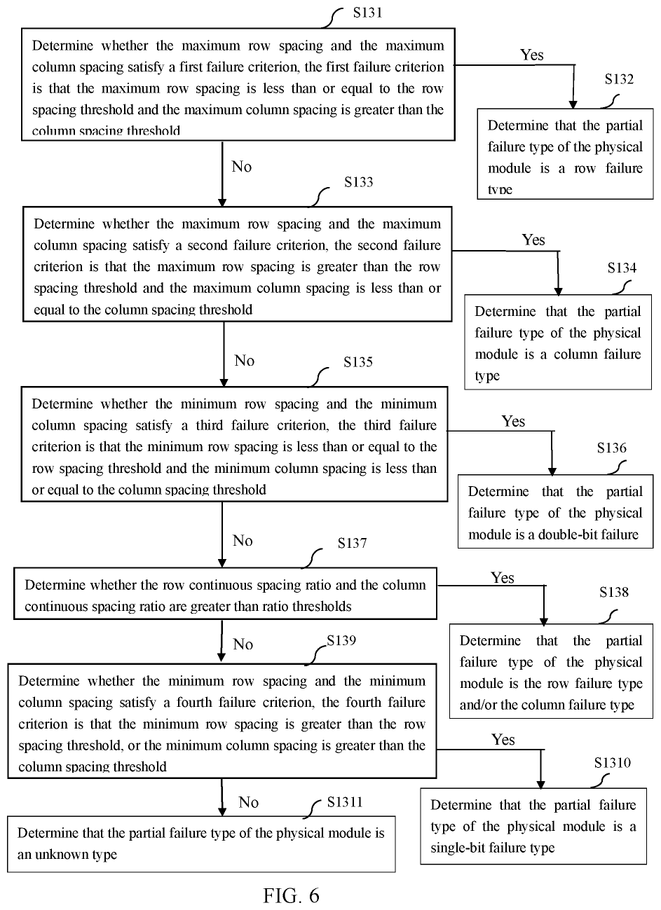

In this embodiment, referring to FIG. 6, specifically, step S13 includes:
Step S131, whether the maximum row spacing and the maximum column spacing satisfy a first failure criterion is determined, the first failure criterion is that the maximum row spacing is less than or equal to the row spacing threshold and the maximum column spacing is greater than the column spacing threshold;
Step S132, if the maximum row spacing and the maximum column spacing satisfy the first failure criterion, it is determined that the partial failure type of the physical module is a row failure type;
Step S133, if the maximum row spacing and the maximum column spacing do not satisfy the first failure criterion, whether the maximum row spacing and the maximum column spacing satisfy a second failure criterion is determined, the second failure criterion is that the maximum row spacing is greater than the row spacing threshold and the maximum column spacing is less than or equal to the column spacing threshold;
Step S134, if the maximum row spacing and the maximum column spacing satisfy the second failure criterion, it is determined that the partial failure type of the physical module is a column failure type;
Step S135, if the maximum row spacing and the maximum column spacing do not satisfy the second failure criterion, whether the minimum row spacing and the minimum column spacing satisfy a third failure criterion is determined, the third failure criterion is that the minimum row spacing is less than or equal to the row spacing threshold and the minimum column spacing is less than or equal to the column spacing threshold;
Step S136, if the maximum row spacing and the maximum column spacing satisfy the third failure criterion, it is determined that the partial failure type of the physical module is a double-bit failure type;
Step S137, if the maximum row spacing and the maximum column spacing do not satisfy the third failure criterion, whether the row continuous spacing ratio and the column continuous spacing ratio are greater than ratio thresholds is determined;
Step S138, if the row continuous spacing ratio and/or the column continuous spacing ratio are greater than the ratio thresholds, it is determined that the partial failure type of the physical module is the row failure type and/or the column failure type;
Step S139, if the row continuous spacing ratio and the column continuous spacing ratio are not greater than the ratio thresholds, whether the minimum row spacing and the minimum column spacing satisfy a fourth failure criterion is determined, the fourth failure criterion is that the minimum row spacing is greater than the row spacing threshold, or the minimum column spacing is greater than the column spacing threshold;
Step S1310, if the minimum row spacing and the minimum column spacing satisfy the fourth failure criterion, it is determined that the partial failure type of the physical module is a single-bit failure type;
Step S1311, if the minimum row spacing and the minimum column spacing do not satisfy the fourth failure criterion, it is determined that the partial failure type of the physical module is an unknown type.

It may be understood that the “row spacing threshold”, “column spacing threshold”, and “ratio thresholds” in the steps may be set according to actual conditions. As an example, the “row spacing threshold” may be set to 2 uniformly, and the “column spacing threshold” may be set to 8 uniformly.

In this embodiment, the maximum row spacing, the minimum row spacing, the maximum column spacing, and the minimum column spacing are used as the first determination parameter to effectively determine the partial failure type of the physical module.

Of course, in other embodiments, the first determination parameter is not limited to the determination parameter in this embodiment. Correspondingly, the process of determining the partial failure type of the physical module is not limited to the form of this embodiment.

In one embodiment, the physical module includes a plurality of storage units arranged in an array. Each storage unit outputs data through a corresponding IO channel.

The method for determining the multi-channel failure category in step S530 includes:
Step S21, the partial failure type of the physical module is determined according to a second determination parameter of the physical module.

The second determination parameter may be obtained before step S21. For example, it may be obtained, but not limited to, after step S4 and before step S520.

In one embodiment, the second determination parameter includes at least a minimum row spacing, a maximum row spacing, a maximum column spacing and a row continuous spacing ratio between the storage units corresponding to each failure data, the row continuous spacing ratio is a ratio of failure data whose row spacing between the corresponding storage units is less than or equal to a row spacing threshold.

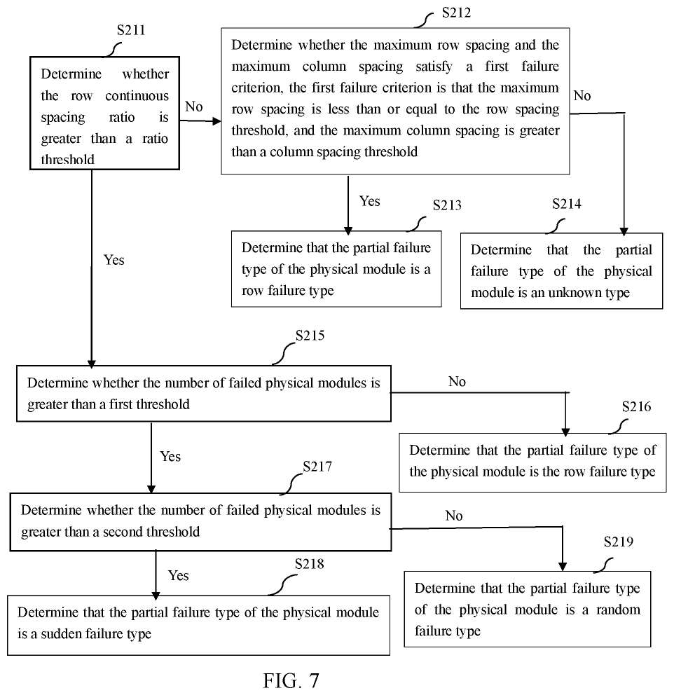

Then, referring to FIG. 7, step S21 may specifically include:
Step S211, whether the row continuous spacing ratio is greater than a ratio threshold is determined;
Step S212, if the row continuous spacing ratio is not greater than the ratio threshold, whether the maximum row spacing and the maximum column spacing satisfy a first failure criterion is determined, the first failure criterion is that the maximum row spacing is less than or equal to the row spacing threshold and the maximum column spacing is greater than a column spacing threshold;
Step S213, if the maximum row spacing and the maximum column spacing satisfy the first failure criterion, it is determined that the partial failure type of the physical module is a row failure type;
Step S214, if the maximum row spacing and the maximum column spacing do not satisfy the first failure criterion, it is determined that the partial failure type of the physical module is an unknown type;
Step S215, if the row continuous spacing ratio is greater than the ratio threshold, whether the number of failed physical modules is greater than a first threshold is determined;
Step S216, if the number of failed physical modules is not greater than the first threshold, it is determined that the partial failure type of the physical module is the row failure type;
Step S217, if the number of failed physical modules is greater than the first threshold, whether the number of failed IO channels is greater than a second threshold is determined;
Step S218, if the number of failed IO channels is greater than the second threshold, it is determined that the partial failure type of the physical module is a sudden failure type;
Step S219, if the number of failed IO channels is not greater than the second threshold, it is determined that the partial failure type of the physical module is a random failure type.

The failure data in the sudden failure type and the random failure type here are data related to IO channel problems.

It is understandable that the “row spacing threshold”, “column spacing threshold”, “ratio threshold”, “first threshold”, and “second threshold” in the steps may be set according to actual conditions. As an example, the “row spacing threshold” may be set to 2 uniformly, and the “column spacing threshold” may be set to 8 uniformly.

In this embodiment, the maximum row spacing, the minimum row spacing, and the maximum column spacing are used as the second determination parameter, which can effectively determine the partial failure type of the physical module.

Of course, in other embodiments, the second determination parameter is not limited to the determination parameter in this embodiment. Correspondingly, the process of determining the partial failure type of the physical module is not limited to the form of this embodiment.

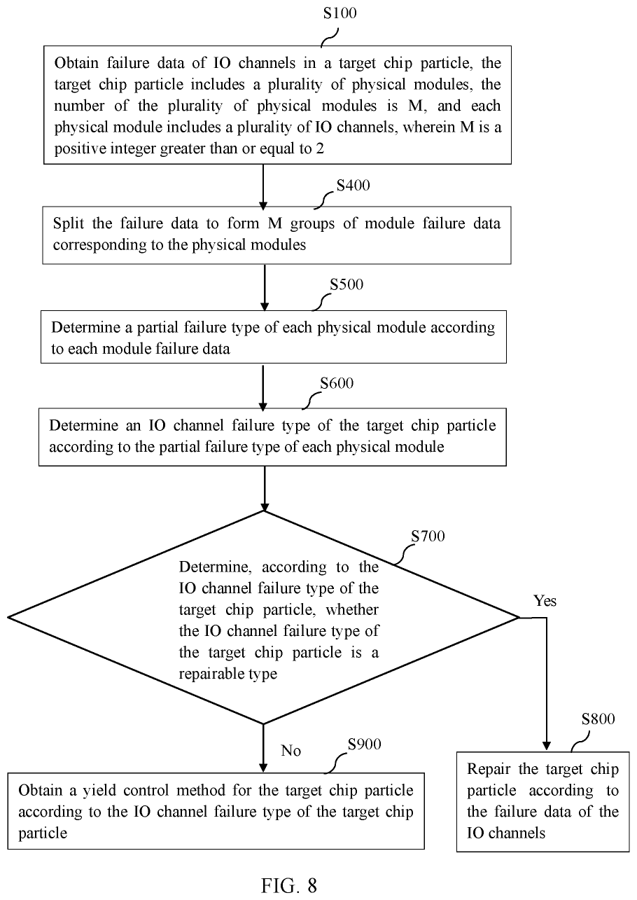

In one embodiment, referring to FIG. 8, after step S600, the method further includes:
Step S700, whether the storage failure type of the target chip particle is a repairable type is determined according to the storage failure type of the target chip particle;
Step S800, if the storage failure type is a repairable type, the target chip particle is repaired according to the failure data of the IO channels.

The repair can effectively improve the yield of the target chip particle.

The repairable type may include, for example, a single-bit failure type. a plurality of replacement units may be provided in the target chip particle. When a storage unit corresponding to the single-bit failure type has an error, the wrong storage unit may be replaced with a replacement unit, so as to repair the target chip particle according to the failure data of the IO channel.

In an embodiment, after step S700, the method further includes:
Step S900, if the storage failure type is not a repairable type, a yield control method for the target chip particle is obtained according to the storage failure type of the target chip particle.

As an example, step S900 may include:
Step S910, a failure cause of the target chip particle is analyzed according to the storage failure type of the target chip particle;
Step S920, the yield control method for the target chip particle is obtained according to the failure cause of the target chip particle.

By analyzing the failure cause, possible problems of the target chip particles may be found, and the yield control method of the chip particle can thus be obtained, which can effectively improve the yield of chip particles produced later.

Specifically, the analysis system may store a plurality of failure causes and a plurality of yield control methods. In addition, the analysis system may store corresponding relationships between the failure causes and the yield control methods. As such, the yield control method of the target chip particle may be obtained according to the failure cause of the target chip particle.

Here, in practical applications, while the yield control method is automatically obtained by an analysis system, engineers can also perform engineering analysis, thereby improving the yield of chip particles more effectively by combining the engineering analysis results with the results obtained by the analysis system.

It should be understood that although various steps in the flowcharts of FIGS. 1 to 8 are displayed in sequence as indicated by the arrows, these steps are not necessarily executed in the order indicated by the arrows. Unless explicitly described herein, the execution of these steps is not limited to a strict order, instead, the steps may be executed in other order. Moreover, at least part of the steps in FIGS. 1 to 8 may include a plurality of steps or a plurality of stages. These steps or stages are not necessarily executed at the same time, but may be executed at different times. These steps or stages are not necessarily executed sequentially, but may be executed alternately with other steps or at least part of the steps or stages in the other steps.

In one embodiment, computer equipment is provided, including a memory and a processor, the memory storing a computer program therein, wherein when the processor executes the computer program, the following steps are implemented:
Step S100, failure data of IO channels in a target chip particle is obtained, the target chip particle including a plurality of physical modules, the number of the plurality of physical modules is M, and each physical module including a plurality of IO channels, wherein M is a positive integer greater than or equal to 2;
Step S400, the failure data is split to form M groups of module failure data corresponding to the physical modules;
Step S500, a partial failure type of each physical module is determined according to each module failure data;
Step S600, a storage failure type of the target chip particle is determined according to the partial failure type of each physical module.

In an embodiment, when the processor executes the computer program, the following steps are further implemented:
Step S200, whether the failure data satisfies a whole failure type criterion is determined;
Step S300, if the failure data satisfies the whole failure type criterion, the storage failure type of the target chip particle is determined according to the whole failure type.

If the failure data does not satisfy the whole failure type criterion, the storage failure type of the target chip particle is determined according to the partial failure type of each physical module.

In one embodiment, a computer-readable storage medium is provided, storing a computer program thereon, wherein when the computer program is executed by a processor, the following steps are implemented:
Step S100, failure data of IO channels in a target chip particle is obtained, the target chip particle including a plurality of physical modules, the number of the plurality of physical modules is M, and each physical module including a plurality of IO channels, wherein M is a positive integer greater than or equal to 2;
Step S400, the failure data is split to form M groups of module failure data corresponding to the physical modules;
Step S500, a partial failure type of each physical module is determined according to each module failure data;
Step S600, a storage failure type of the target chip particle is determined according to the partial failure type of each physical module.

In an embodiment, when the computer program is executed by the processor, the following steps are further implemented:
Step S200, whether the failure data satisfies a whole failure type criterion is determined;
Step S300, if the failure data satisfies the whole failure type criterion, the storage failure type of the target chip particle is determined according to the whole failure type.

If the failure data does not satisfy the whole failure type criterion, the storage failure type of the target chip particle is determined according to the partial failure type of each physical module.

A person of ordinary skill in the art can understand that all or part of the processes in the methods of the foregoing embodiments may be implemented by a computer program instructing relevant hardware. The computer program may be stored in a non-volatile computer-readable storage medium. The computer program, when executed, may include the processes of the embodiments of the above methods. Any reference to the memory, storage, database or other media used in the embodiments provided by the present application may include at least one of non-volatile and volatile memories. The non-volatile memory may include a Read-Only Memory (ROM), a magnetic tape, a floppy disk, a flash memory, or an optical memory. The volatile memory may include a Random Access Memory (RAM) or an external cache memory. Illustratively, rather than limiting, the RAM may be in various forms, such as a Static Random Access Memory (SRAM) or a Dynamic Random Access Memory (DRAM).

In the description of this specification, the description with reference to the terms “one embodiment”, “other embodiment”, etc. means that the specific feature, structure, material or feature described in conjunction with the embodiment or example is included in at least one embodiment or example of the present invention. In this specification, the schematic description of the above terms does not necessarily refer to the same embodiment or example.

The technical features of the above embodiments may be combined arbitrarily. For the purpose of simplicity in description, all the possible combinations of the technical features in the above embodiments are not described. However, as long as the combinations of these technical features do not have contradictions, they shall fall within the scope of the specification.

The foregoing embodiments only describe several implementations of the present application, and their descriptions are specific and detailed, but cannot therefore be understood as limitations to the patent scope of the present invention. It should be noted that a person of ordinary skill in the art may further make variations and improvements without departing from the conception of the present application, and these all fall within the protection scope of the present application. Therefore, the patent protection scope of the present application should be subject to the appended claims.

1. A failure analysis method, comprising:
obtaining failure data of IO channels in a target chip particle, the target chip particle comprising a plurality of physical modules, a number of the plurality of physical modules is M, and each physical module comprising a plurality of IO channels, wherein M is a positive integer greater than or equal to 2;
splitting the failure data to form M groups of module failure data corresponding to the physical modules;
determining a partial failure type of each physical module according to each module failure data; and
determining a storage failure type of the target chip particle according to the partial failure type of each physical module.

2. The failure analysis method according to claim 1, further comprising:
before determining a storage failure type of the target chip particle according to the partial failure type of each physical module, and after obtaining failure data of IO channels in a target chip particle,
determining whether the failure data satisfies a whole failure type criterion;
if the failure data satisfies the whole failure type criterion, determining the storage failure type of the target chip particle according to the whole failure type; or
if the failure data does not satisfy the whole failure type criterion, determining the storage failure type of the target chip particle according to the partial failure type of each physical module.

3. The failure analysis method according to claim 2, wherein the failure analysis method is applied to failure analysis of a storage system, the storage system comprises a plurality of chip particles, a number of the plurality of chip particles is N, and N is a positive integer greater than or equal to 2, and the whole failure type criterion comprises a system-level whole failure criterion and a particle-level whole failure criterion.

4. The failure analysis method according to claim 3, wherein the system-level whole failure criterion comprises a contact failure type criterion, the contact failure type criterion indicates simultaneous failure of failure data of a preset number of IO channels of other chip particles;
the determining whether the failure data satisfies a whole failure type criterion comprises: determining whether the failure data satisfies the contact failure type criterion;
if the failure data satisfies the whole failure type criterion, determining the storage failure type of the target chip particle according to the whole failure type comprises: if the failure data satisfies the contact failure type criterion, determining that the storage failure type of the target chip particle is a contact failure type.

5. The failure analysis method according to claim 4, wherein the particle-level whole failure criterion comprises a block move failure type criterion, the block move failure type criterion indicates that the failure data is test data of block move pattern test;
the determining whether the failure data satisfies a whole failure type criterion further comprises: if the failure data does not satisfy the contact failure type criterion, determining whether the failure data satisfies the block move failure type criterion;
if the failure data satisfies the whole failure type criterion, determining the storage failure type of the target chip particle according to the whole failure type comprises: if the failure data satisfies the block move failure type criterion, determining that the storage failure type of the target chip particle is a block move failure type;
if the failure data does not satisfy the whole failure type criterion, determining the storage failure type of the target chip particle according to the partial failure type of each physical module comprises: if the failure data does not satisfy the block move failure type criterion, determining the storage failure type of the target chip particle according to the partial failure type of each physical module.

6. The failure analysis method according to claim 1, wherein the determining a partial failure type of each physical module according to each module failure data comprises:
determining a module failure category of each physical module according to the module failure data of each physical module, the module failure category comprises a single-channel failure category and a multi-channel failure category;
if the module failure category of the physical module is the single-channel failure category, determining the partial failure type of the physical module according to a method for determining the single-channel failure category; or
if the module failure category of the physical module is the multi-channel failure category, determining the partial failure type of the physical module according to a method for determining the multi-channel failure category.

7. The failure analysis method according to claim 6, wherein the physical module comprises a plurality of storage units arranged in an array, and each storage unit outputs data through a corresponding IO channel;
the method for determining the single-channel failure category comprises:
determining whether a row value and a column value of the storage unit corresponding to the failure data in the physical module are unique;
if the row value and the column value of the storage unit corresponding to the failure data in the physical module are unique, determining that the partial failure type of the physical module is a single-bit failure type; or
if the row value and the column value of the storage unit corresponding to the failure data in the physical module are not unique, determining the partial failure type of the physical module according to a first determination parameter of the physical module.

8. The failure analysis method according to claim 7, wherein the first determination parameter comprises at least a maximum row spacing, a minimum row spacing, a maximum column spacing, a minimum column spacing, a row continuous spacing ratio and a column continuous spacing ratio between the storage units corresponding to each failure data, the row continuous spacing ratio is a ratio of failure data whose row spacing between the corresponding storage units is less than or equal to a row spacing threshold, and the column continuous spacing ratio is a ratio of failure data whose column spacing between the corresponding storage units is less than or equal to a column spacing threshold,
if the row value and the column value of the storage unit corresponding to the failure data in the physical module are not unique, determining the partial failure type of the physical module according to a first determination parameter of the physical module comprises:
determining whether the maximum row spacing and the maximum column spacing satisfy a first failure criterion, the first failure criterion is that the maximum row spacing is less than or equal to the row spacing threshold and the maximum column spacing is greater than the column spacing threshold;
if the maximum row spacing and the maximum column spacing satisfy the first failure criterion, determining that the partial failure type of the physical module is a row failure type;
if the maximum row spacing and the maximum column spacing do not satisfy the first failure criterion, determining whether the maximum row spacing and the maximum column spacing satisfy a second failure criterion, the second failure criterion is that the maximum row spacing is greater than the row spacing threshold and the maximum column spacing is less than or equal to the column spacing threshold;
if the maximum row spacing and the maximum column spacing satisfy the second failure criterion, determining that the partial failure type of the physical module is a column failure type;
if the maximum row spacing and the maximum column spacing do not satisfy the second failure criterion, determining whether the minimum row spacing and the minimum column spacing satisfy a third failure criterion, the third failure criterion is that the minimum row spacing is less than or equal to the row spacing threshold and the minimum column spacing is less than or equal to the column spacing threshold;
if the maximum row spacing and the maximum column spacing satisfy the third failure criterion, determining that the partial failure type of the physical module is a double-bit failure type;
if the maximum row spacing and the maximum column spacing do not satisfy the third failure criterion, determining whether the row continuous spacing ratio and the column continuous spacing ratio are greater than ratio thresholds;
if the row continuous spacing ratio and/or the column continuous spacing ratio are greater than the ratio thresholds, determining that the partial failure type of the physical module is the row failure type and/or the column failure type;
if the row continuous spacing ratio and the column continuous spacing ratio are not greater than the ratio thresholds, determining whether the minimum row spacing and the minimum column spacing satisfy a fourth failure criterion, the fourth failure criterion is that the minimum row spacing is greater than the row spacing threshold, or the minimum column spacing is greater than the column spacing threshold;
if the minimum row spacing and the minimum column spacing satisfy the fourth failure criterion, determining that the partial failure type of the physical module is the single-bit failure type; or
if the minimum row spacing and the minimum column spacing do not satisfy the fourth failure criterion, determining that the partial failure type of the physical module is an unknown type.

9. The failure analysis method according to claim 6, wherein the physical module comprises a plurality of storage units arranged in an array, and each storage unit outputs data through a corresponding IO channel;
the method for determining the multi-channel failure category comprises:
determining the partial failure type of the physical module according to a second determination parameter of the physical module.

10. The failure analysis method according to claim 9, wherein the second determination parameter comprises at least a minimum row spacing, a maximum row spacing, a maximum column spacing and a row continuous spacing ratio between the storage units corresponding to each failure data, the row continuous spacing ratio is a ratio of failure data whose row spacing between the corresponding storage units is less than or equal to a row spacing threshold,
determining the partial failure type of the physical module according to the second determination parameter comprises:
determining whether the row continuous spacing ratio is greater than a ratio threshold;
if the row continuous spacing ratio is not greater than the ratio threshold, determining whether the maximum row spacing and the maximum column spacing satisfy a first failure criterion, the first failure criterion is that the maximum row spacing is less than or equal to the row spacing threshold and the maximum column spacing is greater than a column spacing threshold;
if the maximum row spacing and the maximum column spacing satisfy the first failure criterion, determining that the partial failure type of the physical module is a row failure type;
if the maximum row spacing and the maximum column spacing do not satisfy the first failure criterion, determining that the partial failure type of the physical module is an unknown type;
if the row continuous spacing ratio is greater than the ratio threshold, determining whether the number of failed physical modules is greater than a first threshold;
if the number of failed physical modules is not greater than the first threshold, determining that the partial failure type of the physical module is the row failure type;
if the number of failed physical modules is greater than the first threshold, determining whether the number of failed IO channels is greater than a second threshold;
if the number of failed IO channels is greater than the second threshold, determining that the partial failure type of the physical module is a sudden failure type; or
if the number of failed IO channels is not greater than the second threshold, determining that the partial failure type of the physical module is a random failure type.

11. The failure analysis method according to claim 1, further comprising: after determining a storage failure type of the target chip particle according to the partial failure type of each physical module,
determining, according to the storage failure type of the target chip particle, whether the storage failure type of the target chip particle is a repairable type; and
if the storage failure type is a repairable type, repairing the target chip particle according to the failure data of the IO channels.

12. The failure analysis method according to claim 11, further comprising: after determining, according to the storage failure type of the target chip particle, whether the storage failure type of the target chip particle is a repairable type,
if the storage failure type is not a repairable type, obtaining a yield control method for the target chip particle according to the storage failure type of the target chip particle.

13. The failure analysis method according to claim 12, wherein if the storage failure type is not a repairable type, obtaining a yield control method for the target chip particle according to the storage failure type of the target chip particle comprises:
analyzing a failure cause of the target chip particle according to the storage failure type of the target chip particle; and
obtaining the yield control method for the target chip particle according to the failure cause of the target chip particle.

14. A computer equipment, comprising a memory and a processor, the memory storing a computer program, wherein when the processor executes the computer program, the steps of the failure analysis method according to claim 1 are implemented.

15. A computer-readable storage medium, storing a computer program, wherein when the computer program is executed by a processor, the steps of the failure analysis method according to claim 1 are implemented.
